(19) United States
(12) Patent Application Publication
(10) Pub. No.: US 2008/0272503 A1
(43) Pub. Date: Nov. 6, 2008

(54) Semiconductor Device and Method for Making Same

(76) Inventor: Henning Mieth, Jahnsdorf (DE)

Correspondence Address: SLATER & MATSIL, L.L.P., 17950 PRESTON ROAD, SUITE 1000, DALLAS, TX, 75252, US

(21) Appl. No.: 11/744,725

(22) Filed: May 4, 2007

(51) Int. Cl. H01L 23/28; H01L 21/56

(52) U.S. Cl. 257/787; 438/127; 257/E23.116; 257/E21.506

(57) ABSTRACT

A transfer mold process for encapsulation of a matrix array package of dice on a substrate is proposed wherein the flow of the mold compound between dice is at least partly obstructed. In other words, the flow velocity of the mold compound between dice is constrained with the goal of approximating it to the flow velocity above the dice. It is to be understood that every limitation of the flow velocity between the dice, even if it does not result in equal or uniform velocity throughout the cross-sectional area, will bring about a positive effect in terms of reducing the clustering of filler particles in certain areas of the mold compound. The semiconductor device thus produced is part of the present disclosure.

### TECHNICAL FIELD

Disclosed herein is a semiconductor device and a method for making a semiconductor device. The method relates generally to manufacturing electronic circuit assemblies, and in particular to the molding process of a molded matrix array package.

### BACKGROUND

In the manufacture of semiconductor devices, dice are arranged on a substrate in a matrix array. Subsequently, the dice in the matrix array may be encapsulated in a curable mold compound. After the molding process, the individual dice may be singulated into packages. The molding process may involve placing a mold over the array of dice, filling the space between the mold, the dice and the substrate which supports the dice with the mold compound and after the mold compound has cured, removing the mold. A mold compound usually used in the process comprises a resin material with filler particles evenly distributed therein.

During the molding process, migration of the filler particles may occur. The mold compound enters the mold through an inlet and is forced to an outlet of the mold which primarily serves to enable discharge of the air which is displaced by the inflowing mold compound. Thus, the mold and the substrate with the dice arranged on its surface form walls of a flow channel through which the mold compound flows during the molding process. Due to the friction between the mold compound and these walls, the velocity of the mold compound shows an increasing gradient towards the walls, i.e., the mold compound moves significantly slower in close proximity to the walls than it does in the middle between two walls. This decline of velocity, observed in the cross-sectional direction of the mold flow from center to edge, i.e., towards a wall of the flow channel, leads to an increased probability of collision of filler particles with each other which in turn leads to migration of filler particles away from the walls of the flow channel and towards the forefront of the innermost streak of the flowing mold compound. Obviously, this effect is amplified by the fact that the flow channel is wider between the dice than it is above the dice as the mold compound can flow significantly faster in those wider areas.

The result of this is that the originally evenly distributed filler particles concentrate in certain areas of the stream, thereby creating other areas of significantly lower concentration of filler particles in the resin material. After the mold compound has cured, the mold is removed from the substrate. The cured mold compound now constitutes a housing for the semiconductor device.

In a subsequent step, performed either before or after the individual dice are separated into semiconductor devices, each of the devices is marked, usually by employment of a laser beam which is directed over the surface of the housing so as to write the manufacturer's name, the device type, etc., onto that surface by changing certain properties of the material due to the heat transferred.

However, because the laser light absorption is different for the resin material and the filler particles of the mold compound, the characters written in surface areas of high filler particle concentration will suffer from low contrast which results in poor legibility. This is a serious quality issue and may lead to a significant yield loss.

A transfer mold process for encapsulation of a matrix array package of dice on a substrate is proposed wherein the flow of the mold compound between dice is obstructed. In other words, the flow velocity of the mold compound between dice is constrained with the goal of approximating it to the flow velocity above the dice. It is to be understood that every limitation of the flow velocity between the dice, even if it does not result in equal or uniform velocity throughout the cross-sectional area, will bring about a positive effect in terms of reducing the clustering of filler particles in certain areas of the mold compound. One way to achieve a slower mold flow in those areas is to reduce the cross-sectional area of the flow channel between dice, i.e., to reduce the clearance of the mold over the substrate. The result of this is that the mold compound cannot flow substantially faster between the dice than above the dice. Thereby, the segregation of filler particles in the mold compound is reduced.

### SUMMARY OF THE INVENTION

In one embodiment, a flow blocker is disposed between dice on the substrate. The flow blocker may, for instance, consist of substrate material. Alternatively, the flow blocker may consist of a printable material, as for instance a polymer resin, die attach, etc. Both alternatives involve operations being performed on the matrix array package before the mold is placed over the substrate.

For instance, flow blockers built from substrate material may be obtained by grinding or etching the surface of the substrate so as to create grooves or recesses inside which a die or dice can be mounted. The substrate material surrounding the grooves or recesses then constitutes a flow blocker. The depth of the grooves or recesses may be selected so as to be substantially equal to the height of a die or, as the case may be, the combined height of a die and a layer of die attach material underneath the die, the combined height of the die and solder bumps underneath the die, and so on. The width of the grooves or recesses may be selected so as to leave a passage for the mold compound on either side of the die mounted therein whose width is substantially equal to the height of the passage above the die.

Flow blockers made of a printable material may be printed on the substrate's surface prior to installing the dice. The thickness of the flow blockers printed on the substrate may be selected so as to be substantially equal to the height of a die, the combined height of the die and a layer of die attach material or solder bumps underneath the die, and so on. The width of the printed flow blockers may be selected so as to leave a passage for the mold compound on either side of the die mounted therebetween whose width is substantially equal to the height of the passage above the die.

Both alternatives of this embodiment provide for the use of a mold which has a substantially flat inner surface. It is, of course, also possible to make the flow blockers so as to fill the space between dice entirely, without departing from the basic idea of this disclosure. For instance, a squeegee or wiper may be used to fill the space between dies with a curable compound prior to placing a mold with a flat inner surface over the matrix array package.

In another embodiment, the height of the package is reduced in the areas between dice. This may, for instance, be achieved by using a mold whose inner surface is rippled, i.e., the surface has ridges which are arranged between dice when the mold is placed over the substrate. The height of the ridges may be selected so as to be substantially equal to the height of the die, the combined height of the die and a layer of die attach material or solder bumps underneath the die, and so on. The width of the ridges may be selected so as to leave a passage for the mold compound on either side of the die mounted therebetween on the substrate whose width is substantially equal to the height of the passage above the die. Each of these ridges narrows the space between two dice in a similar manner as the flow blockers described above. There is, however, a difference in that the ridges protrude downwards from the mold while the flow blockers protrude upwards from the substrate. Either way, the width of the diverse segments of the flow channel (those above the die and those beside the die) is approximated or even equalized. After singulation, the semiconductor devices have flattened edges, i.e., margin areas of their housings have a relatively small height, compared to the rest of the housing. In other words, the thickness of the housing is reduced in at least one margin area of the semiconductor device.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a matrix array device arranged inside a conventional mold tool;

FIG. 2 shows a matrix array package with flow blockers consisting of substrate material;

FIG. 3 shows a matrix array package with flow blockers consisting of die attach material; and

FIG. 4 shows a mold tool with ridges extending between dice.

### DETAILED DESCRIPTION OF ILLUSTRATIVE EMBODIMENTS

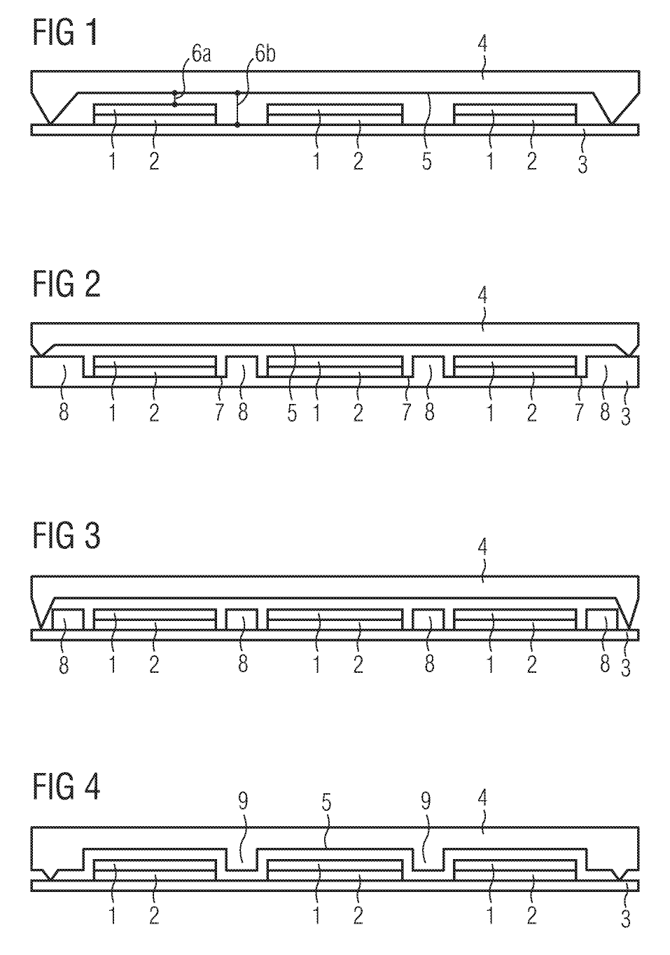

In FIG. 1, the transfer mold process for encapsulating a matrix array package as presently used is illustrated. A number of dice 1 is evenly distributed over the surface of a substrate 3 and each die is attached to the substrate by means of a layer of die attach material 2 disposed between the underside of the die 1 and the surface of the substrate 3. A mold tool 4 having a flat inner surface 5 is placed over the matrix array of dice 1. The clearance between the inner surface 5 of the mold tool 4 and the upper surfaces of the dice 1 or the substrate 3, respectively, forms a flow channel for a mold compound used to encapsulate the package, thereby forming a housing for each die 1. After curing of the mold compound, which comprises a resin material and filler particles, the individual dice 1 are singulated by sawing the matrix array package.

As can be seen from FIG. 1, the clearance 6a above a die 1 is relatively narrow compared with the clearance 6b of the mold tool 4 over the substrate 3 in areas between dice 1. Therefore, the flow resistance in these areas is relatively low and the mold compound can flow relatively fast. In contrast, the mold compound above a die 1 flows relatively slow. This difference in flow velocities leads to an increase of the separation of the filler particles in certain areas of the matrix array which results in so-called flow marks. As previously discussed, the separation of filler particles and resin material has adverse effects on the quality of the laser markings.

A first embodiment of the proposed method and the semiconductor device thus produced is illustrated in FIG. 2. There, each die 1 is arranged inside a recess 7 of the substrate 3 which may have been formed using a dry etch process. The remainder of substrate material between any two recesses 7 forms a flow blocker 8 for the mold compound. The die 1 has been attached to the ground of the recess 7 using a die attach material 2. The combined thickness of the die attach material 2 and the die 1 determines the height of the upper surface of the die 1 over the ground of the recess 7. In the embodiment shown, the depth of the recess 7 is substantially equal to the height of the upper surface of the die 1 over the ground of the recess 7. In other words, the height of the flow blocker 8 is substantially equal to the height of the upper surface of the die 1 over the surface of the substrate 3.

The width of the recess 7 is selected so as to be equal to the sum of the width of the die 1 installed therein plus twice the distance of the mold tool 4 from the upper surface of the die 1. In other words, on either side of the die 1 a flow channel is formed whose width is equal to the height of the flow channel above a die 1 so that every section of the flow channel provided between the mold tool 4 and the matrix array of dice 1 on the substrate 3 is equally wide. This provides for a uniform mold compound flow.

In FIG. 3, another embodiment of the proposed method and the semiconductor device thus produced is illustrated. It is similar to the first embodiment described above in that the flow of the mold compound between dice 1 is obstructed by a flow blocker 8. However, in this embodiment the flow blocker 8 consists of die attach or a comparable material. For example, the die attach material that forms the flow blockers 8 has been printed on the substrate 3 together with the layers of die attach material 2 used to install the dice 1 on the surface of the substrate 3. Yet, the flow blockers 8 are higher than the layers of die attach material 2 underneath the dice 1. This may be achieved by printing with a step stencil or a second print step, in which also a different material may be used. Specifically, the height of the flow blockers 8 is substantially equal to the height of the upper surface of the die 1 over the surface of the substrate 3. The width of the flow blockers 8 is selected so as to form a flow channel on either side of each die 1 whose width is equal to the height of the flow channel over a die 1. As in the first embodiment, every section of the flow channel provided between the mold tool 4 and the matrix array of dice 1 on the substrate 3 is equally wide.

In the embodiment illustrated in FIG. 4, the flow of the mold compound is also obstructed in areas between dice 1. However, in this embodiment the height of the package is reduced in the areas between dice 1. To this end, the mold tool 4 does not have a flat inner surface 5. Rather, the inner surface 5 of the mold tool 4 is provided with ridges 9 which, when the mold tool 4 is placed over the matrix array of dice 1 on the substrate 3, are arranged in areas between dice 1. In the embodiment shown, the ridges 9 are fin-like extensions protruding from the inner surface 5 of the mold tool 4 downwards. In other embodiments, the ridges 9 may be pleats or corrugations formed in the sheet-like material of the mold tool 4. The height and width of the extensions 9 are selected so as to provide a flow channel whose width is substantially equal in all sections or branches above or beside a die 1.

According to the conventional method described with respect to FIG. 1 as well as in the proposed methods disclosed herein in general terms and in illustrated embodiments, the individual dice 1 may be singulated into semiconductor devices. The singulation process may involve cutting or sawing the matrix array package to pieces after the mold tool 4 has been removed. The cutting or sawing of the matrix array package is done along lines which run through areas between dice such that the dice 1 will not be damaged. After singulation, each housing of a semiconductor device will comprise one or more segments of a flow blocker, if such a flow blocker has had a greater width than the sawing or cutting tool used in the singulation process.

What is claimed is:

1. A transfer mold process for encapsulation of a matrix array package of dice on a substrate, wherein flow of a mold compound is at least partly obstructed for a more uniform mold flow over the matrix array package.

2. The transfer mold process of claim 1, wherein a cross-sectional area of a flow channel is at least partly reduced.

3. The transfer mold process of claim 2, wherein a flow blocker is disposed between dice on the substrate.

4. The transfer mold process of claim 3, wherein the flow blocker comprises substrate material.

5. The transfer mold process of claim 1, wherein grooves or recesses are created in a surface of the substrate inside which a die or dice can be mounted.

6. The transfer mold process of claim 5, wherein a depth of the grooves or recesses is selected so as to be substantially equal to a height of an upper surface of the die over the substrate.

7. The transfer mold process of claim 5, wherein a width of the grooves or recesses is selected so as to leave a passage for the mold compound on either side of the die mounted therein whose width is substantially equal to the height of the passage above the die.

8. The transfer mold process of claim 3, wherein the flow blocker comprises an attached material.

9. The transfer mold process of claim 8, wherein a height of the flow blocker is selected so as to be substantially equal to a height of an upper surface of the dice on the substrate.

10. The transfer mold process of claim 8, wherein a width of the flow blocker is selected so as to leave a passage for the mold compound on either side of the dice mounted therebetween whose width is substantially equal to the height of the passage above the die.

11. The transfer mold process of claim 2, wherein a height of the package is reduced in the areas between dice.

12. The transfer mold process of claim 11, wherein a mold tool is used, the mold tool having an inner surface with ridges that are arranged between dice when the mold tool is placed over the substrate.

13. The transfer mold process of claim 12, wherein a height of the ridges is selected so as to be substantially equal to a height of an upper surface of the dice over the substrate.

14. The transfer mold process of claim 12, wherein a width of the ridges is selected so as to leave a passage for the mold compound on either side of the dice mounted therebetween on the substrate whose width is substantially equal to the height of the passage above the die.

15. A semiconductor device, comprising at least one semiconductor die on a substrate, the semiconductor die being encapsulated in a curable mold compound such that the mold compound forms a housing of the semiconductor device, wherein the housing is made according to a transfer mold process of claim 1.

16. A semiconductor device, comprising at least one semiconductor die on a substrate, the semiconductor die being encapsulated in a curable mold compound such that the mold compound forms a housing of the semiconductor device, wherein the housing further comprises at least one segment of at least one flow blocker.

17. The semiconductor device of claim 16, wherein the at least one flow blocker comprises substrate material.

18. The semiconductor device of claim 16, wherein the at least one flow blocker comprises an attached material.

19. A semiconductor device, comprising at least one semiconductor die on a substrate, the semiconductor die being encapsulated in a curable mold compound such that the mold compound forms a housing of the semiconductor device, wherein the housing has a thickness that is reduced in at least one margin area of the semiconductor device.
